(19) United States
(12) Patent Application Publication
(10) Pub. No.: US 2024/0373560 A1
(43) Pub. Date: Nov. 7, 2024

(54) PACKAGE SUBSTRATE HAVING EMBEDDED ELECTRONIC COMPONENT MOUNTED ON CORE OF THE PACKAGE SUBSTRATE

(71) Applicant: QUALCOMM Incorporated, San Diego, CA (US)

(72) Inventors: Seongryul CHOI, Seongnam (KR); Kuiwon KANG, San Diego, CA (US); Hong Bok WE, San Diego, CA (US); Jung Won PARK, Gumi (KR)

(21) Appl. No.: 18/310,277

(22) Filed: May 1, 2023

(51) Int. Cl. H05K 1/18; H01L 21/48; H01L 21/56; H01L 23/00; H01L 23/31; H01L 23/498

(52) U.S. Cl. CPC H05K 1/186; H01L 21/4846; H01L 21/56; H01L 23/3121; H01L 23/49838; H01L 24/08; H01L 24/32; H01L 24/80; H01L 24/83; H01L 2224/08225; H01L 2224/32225; H01L 2224/80203; H01L 2224/80801; H01L 2224/83104; H01L 2224/83192; H05K 2201/10015

(57) ABSTRACT

In an aspect, a substrate is disclosed that includes an electronic component including a lower planar surface having one or more electronic component terminals, a core having an upper planar surface facing the lower planar surface of the electronic component; a patterned metallization layer over the upper planar surface of the core, wherein the patterned metallization layer is connected to the one or more electronic component terminals at the lower planar surface of the electronic component; one or more dielectric layers disposed over the upper planar surface of the core; and a cavity formed within the one or more dielectric layers, wherein the electronic component is located in the cavity and over the upper planar surface of the core.

### FIELD OF DISCLOSURE

The present disclosure generally relates to a package substrate, and more particularly, to a package substrate having an embedded electronic component mounted on a core of the package substrate.

### BACKGROUND

Integrated circuit (IC) technology has achieved great strides in advancing computing power through miniaturization of electrical components. An IC may be implemented in the form of an IC chip that has a set of circuits integrated thereon. In some implementations, one or more IC chips can be physically carried and protected by an IC package, where various power and signal nodes of the one or more IC chips can be electrically coupled to respective conductive terminals of the IC package via electrical paths formed in a package substrate of the IC package. Various packaging technologies can be found in many electronic devices, including processors, servers, radio frequency (RF) integrated circuits, etc. Advanced packaging and processing techniques can be used to implement complex devices, such as multi-electronic component devices and system on a chip (SOC) devices, which may include multiple function blocks, with each function block designed to perform a specific function, such as, for example, a microprocessor function, a graphics processing unit (GPU) function, a communications function (e.g., Wi-Fi, Bluetooth, and other communications), and the like.

In some implementations, embedded electronic components, such as deep trench capacitors, have been incorporated in IC packaging for performance improvement and package size reduction. One factor driving the use of such embedded electronic components is the desire for obtaining small form factor products with equivalent or better electrical performance than their larger electronic components counterparts. Depending on the size and/or thickness of the package substrate and the size and/or the process node of the IC Chip carried thereon, the process for embedding an electronic component in a package substrate in one packaging task may not be suitable for another packaging task.

Accordingly, there is a need for improved methods for embedding an electronic component in a substrate, such as a package substrate, that may be suitable for a broader variety of packaging tasks.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a substrate includes an electronic component including a lower planar surface having one or more electronic component terminals, a core having an upper planar surface facing the lower planar surface of the electronic component; a patterned metallization layer over the upper planar surface of the core, wherein the patterned metallization layer is connected to the one or more electronic component terminals at the lower planar surface of the electronic component; one or more dielectric layers disposed over the upper planar surface of the core; and a cavity formed within the one or more dielectric layers, wherein the electronic component is located in the cavity and over the upper planar surface of the core.

In an aspect, an electronic device includes a substrate including, an electronic component including a lower planar surface having one or more electronic component terminals, a core having an upper planar surface facing the lower planar surface of the electronic component; a patterned metallization layer over the upper planar surface of the core, wherein the patterned metallization layer is connected to the one or more electronic component terminals at the lower planar surface of the electronic component; one or more dielectric layers disposed over the upper planar surface of the core; and a cavity formed within the one or more dielectric layers, wherein the electronic component is located in the cavity and over the upper planar surface of the core.

In an aspect, a method of forming a substrate includes forming a first patterned metallization layer over an upper planar surface of a core, forming one or more dielectric layers over the upper planar surface of the core and at least a portion of the first patterned metallization layer; forming a cavity in the one or more dielectric layers; mounting an electronic component in the cavity, wherein the electronic component includes a lower planar surface having one or more electronic component terminals; and connecting the one or more electronic component terminals to the first patterned metallization layer.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings, which are presented solely for illustration and not limitation of the disclosure.

FIG. 1 is a cross-sectional view of a first example substrate with an embedded electronic component, according to aspects of the disclosure.

FIG. 2 is a cross-sectional view of a second example substrate with an embedded electronic component, according to aspects of the disclosure.

FIG. 3 is a cross-sectional view of an example deep trench capacitor (DTC), according to aspects of the disclosure.

FIG. 4 is a cross-sectional view of an example substrate, according to aspects of the disclosure.

FIG. 5 is a cross-section of view of an example substrate, according to aspects of the disclosure.

FIGS. 6A through 6G illustrate example steps undertaken in fabricating a substrate, according to aspects of the disclosure.

FIG. 7 is a flowchart showing an example method for fabricating a substrate, according to aspects of the disclosure.

FIG. 8 illustrates a profile view of a package that includes a surface mount substrate, an integrated device, and an integrated moisture sensor device, according to aspects of the disclosure.

FIG. 9 illustrates an exemplary flow diagram of a method for fabricating a package that includes a substrate, an integrated device, and an integrated passive device.

FIG. 10 illustrates various electronic devices that may integrate an electronic component, an electronic circuit, an integrated device, an integrated passive device, a passive component, a package, and/or a device package described herein.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

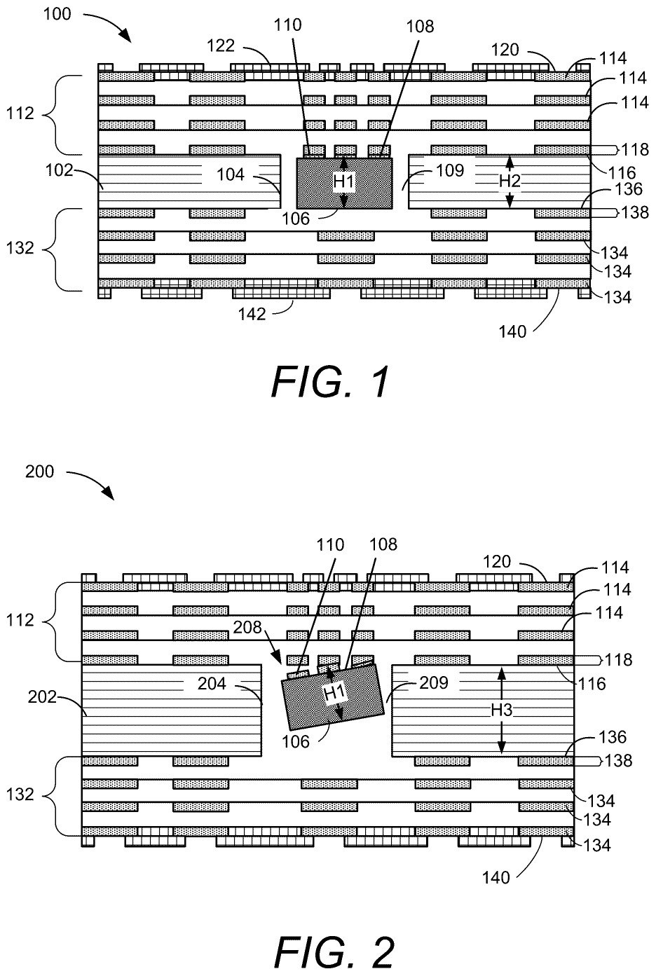

FIG. 1 is a cross-sectional view of a first example substrate 100 with an embedded electronic component, according to aspects of the disclosure. In this example, the substrate 100 includes a core 102 having a cavity 104 that extends entirely through the core 102. An electronic component 106 is disposed within the cavity 104. The electronic component 106 has an upper surface 108 with metal terminals 110 that provide an electrical connection to the electronic component 106. In accordance with various aspects of the disclosure, the electronic component 106 may be one or more of an active electronic component, a passive electronic component (e.g., a deep trench capacitor (DTC)), a die, etc.

In accordance with various aspects of the disclosure, the substrates described herein (e.g., substrate 100) that include a core and an embedded electronic component are directed to package substrates. A package substrate is the part of an integrated circuit package that gives the board its mechanical strength and allows it to connect with external devices. Such package substrates are to be distinguished from other substrates, such as the substrates that may be included in the embedded electronic component itself, dies including substrates (e.g., silicon substrates or other similar electronic devices), etc.

The substrate 100 further includes a plurality of dielectric layers 112 and corresponding patterned metallization layers 114 overlying an upper surface 116 of the core 102. A patterned metallization layer 118 is disposed at the upper surface 116 of the core 102 to provide an electrical connection between the metal terminals 110 of the electronic component 106 and the patterned metallization layers 114. In an aspect, the same dielectric resin material as used in forming the plurality of dielectric layers 112 may be used in the regions 109 of the cavity 104 between the sidewalls of the electronic component 106 and the sidewalls of the core 102. Dispensing a dielectric resin over the electronic component 106 and in the regions 109 assists in securing the electronic component 106 within the cavity 104 so that the metal terminals 110 remain in electrical contact with corresponding portions of the patterned metallization layer 118 once the dielectric resin is cured.

In an aspect, an uppermost patterned metallization layer 114 at an upper surface 120 of the substrate 100 is connected to a plurality of metal terminals 122. The patterned metallization layers 114 provide a conductive path between the metal terminals 110 of the electronic component 106 and the metal terminals 122. In an aspect, the plurality of metal terminals 122 may be configured for connection to an electronic package of a surface-mounted device (not shown in FIG. 1).

In an aspect, a further plurality of dielectric layers 132 and corresponding patterned metallization layers 134 overlie a lower surface 136 of the core 102. Here, a patterned metallization layer 138 is disposed over the lower surface 136 of the core 102. A lowermost patterned metallization layer 134 at a lower surface 140 of the substrate 100 is connected to a plurality of metal terminals 142. The patterned metallization layers 134 provide a conductive path to the metal terminals 142. In an aspect, the plurality of metal terminals 142 may be configured for connection to an electronic package of a further surface-mounted device (not shown in FIG. 1) or to a circuit board for connection with other devices.

In FIG. 1, the electronic component 106 has a height H1 that is substantially the same as the thickness H2 of the core 102. During the manufacture of the substrate 100, the electronic component 106 is inserted in the cavity 104 before a dielectric resin is injected to fill the regions 109 between the cavity 104 and electronic component 106. During insertion, the electronic component 106 is carefully aligned within the cavity 104 to ensure that the metal terminals 110 properly contact and electrically bond with the corresponding portions of the patterned metallization layer 118. Additionally, the injection of the dielectric resin in the regions 109 should be undertaken with care so as not to disturb the initial alignment of the electronic component 106. In an aspect, the dielectric resin, once cured, secures the electronic component 106 at its proper location within the cavity 104.

In scenarios in which the height H1 of the electronic component 106 and thickness H2 of the core 102 are substantially the same, the insertion of the electronic component 106 in the cavity 104 and subsequent injection and cure of the dielectric resin may be implemented using the processing technology as described with reference to FIG. 1. In an example, the height H1 of the electronic component and the thickness H2 of the core 102 in FIG. 1 may each be equal to or less than about 760 micrometers.

Although the structure of the substrate 100 shown in FIG. 1 has been suitable for use in many high-performance applications (e.g., compute and automotive applications), current trends are directed to applications requiring substrates having larger body sizes. However, substrates having large bodies present unique design and manufacturing issues that must be addressed (e.g., substrate warpage, a need for larger cavity sizes, a need for larger keep-out zones, etc.). These issues may be addressed, at least in part, by employing thick cores in the design and manufacture of such substrates. For example, warpage control is more easily achieved with thick cores than with thin cores. Additionally, the need for larger cavity sizes and keep-out zones can be met by employing such thick cores.

However, substrates employing thick cores may be difficult to manufacture using the same packaging technologies that are used in manufacturing substrates having thin cores of the type described in connection with FIG. 1. With thick cores, there is a significant gap between the electronic component and the cavity resulting from the increased depth of the cavity compared to the height of the electronic component (e.g., the thick core has a thickness that is greater than the height of the electronic component). In such thick core scenarios, it may be difficult or impossible to fill the gap surrounding the electronic component with the dielectric resin in a manner that maintains the proper initial alignment of the electronic component in the cavity during the resin injection. Further, it may be difficult or impossible to inject a sufficient amount of dielectric resin in the gap to secure the electronic component at its desired position once the dielectric resin is cured.

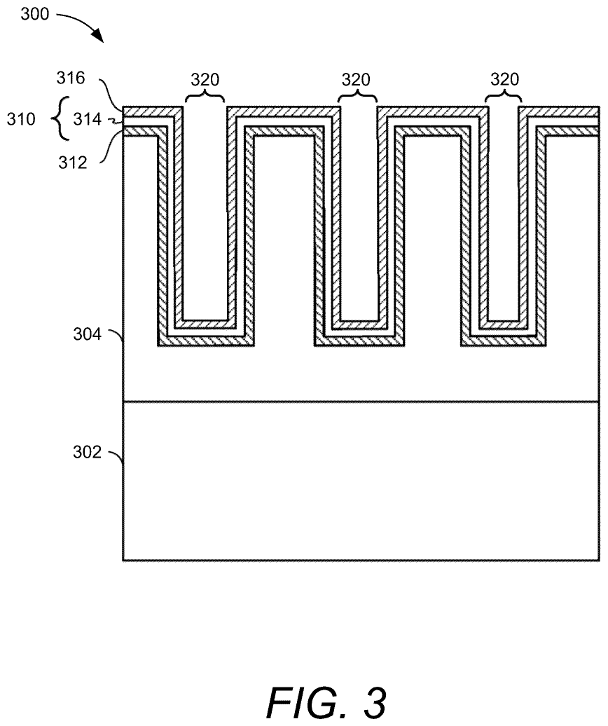

FIG. 2 is a cross-sectional view of an example substrate 200 with an embedded electronic component, according to aspects of the disclosure. In this example, it is assumed that the substrate 200 has been manufactured using the same processing operations as used to manufacture the substrate 100 shown in FIG. 1. For purposes of simplicity, certain reference numbers used in FIG. 1 have also been used to designate similar elements in FIG. 2.

In the example shown in FIG. 2, the substrate 200 differs from the substrate 100 of FIG. 1 in that the substrate 200 employs a thick core 202 having a thickness H3 that is greater than the height H1 of the electronic component 106. In accordance with certain aspects of the disclosure, the thickness H3 is greater than about 760 micrometers and, as such, is thicker than the electronic component 106 and its thin core 102 counterpart. In certain scenarios, the thick core may have a thickness that is substantially greater than 760 micrometers (e.g., 820 micrometers, 1240 micrometers, etc.).

The substrate 200 has a cavity 204 that is substantially deeper than the cavity 104 of the substrate 100. As such, it becomes more difficult to align the metal terminals 110 with the corresponding portions of the patterned metallization layer 118 during the initial placement of the electronic component 106 within the cavity 204. Initial misalignment of the electronic component 106 may fail to establish an electrical connection between the metal terminals 110 and corresponding portions of the patterned metallization layer 118. Additionally, it becomes challenging to correctly fill the cavity 209 (e.g., particularly including the extended regions of the cavity 209) with an amount of dielectric resin that, once cured, properly surrounds and secures the electronic component 106 in place within the cavity 204. An insufficient fill of the cavity 204 with the dielectric resin can lead to subsequent delamination of the electronic component 106 from electrical contact with the corresponding portions of the patterned metallization layer 118 once the substrate 200 is incorporated in a more extensive electronic system (e.g., automobile sensors/computers, mobile devices, or any other type of electronic device as described herein). In FIG. 2, an instance of delamination is shown at region 208, where some of the metal terminals 110 have pulled away from the corresponding portions of the patterned metallization layer 118.

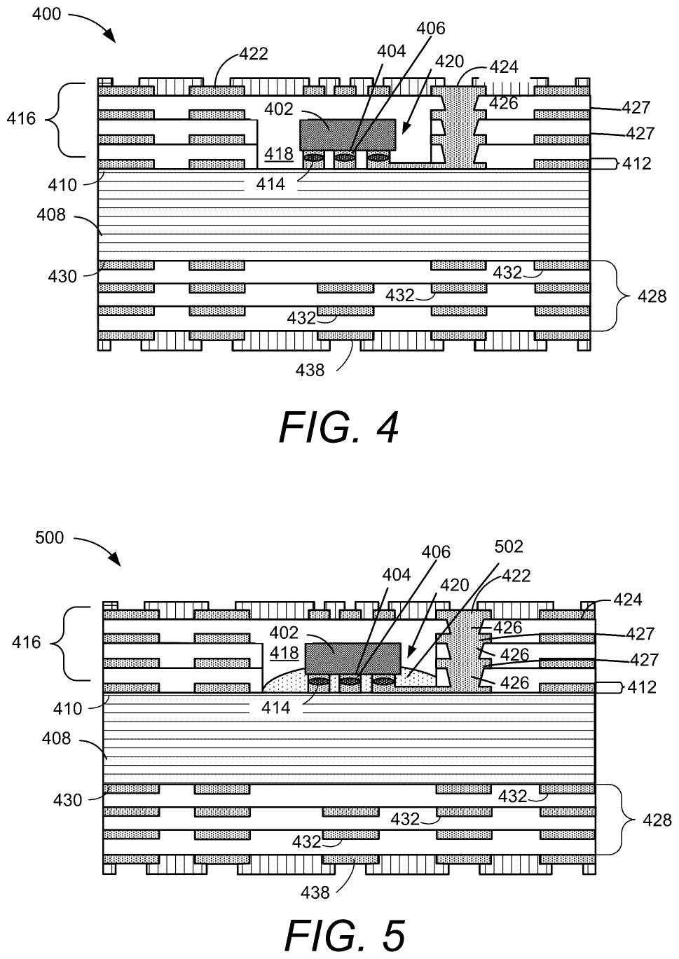

According to certain aspects of the disclosure, the electronic component may be a DTC. FIG. 3 is a cross-sectional view of an example DTC 300, according to aspects of the disclosure. In FIG. 3, a capacitor 310 is deposited in trenches 320 of an insulator 304 on a substrate 302. The capacitor 310 may include a metal layer 312, a dielectric layer 314, and a metal layer 316. The dielectric layer 314 separates the metal layer 312 from the metal layer 316. The metal layers 312, 316 form electrodes of the capacitor 310 and may be connected to terminals at, for example, a surface (see, e.g., the upper surface 108 with metal terminals 110 of electronic component 106 shown in FIG. 1). In some scenarios, the capacitors are formed from an array of deep trenches in a substrate and filled with an electrical insulator (e.g., a dielectric) between layers of electrodes. In some scenarios, the capacitors are attached on the land side under an integrated circuit die shadow (land-side capacitor: LSC) or adjacent to the die on the die side (die-side capacitor: DSC).

Certain aspects of the disclosure are implemented with a recognition of the problems associated with using existing processing technologies to manufacture substrates having thick cores. In accordance with certain aspects of the disclosure, the electronic component may be embedded within a cavity formed in the dielectric layers and patterned metal layers and oriented with its contact side facing an upper portion of the thick core. The contact face-down embedded structure allows the cavity to be filled with the dielectric resin filling without voids that may otherwise lead to failure of the substrate. In accordance with certain aspects of the disclosure, the thickness of the core is no longer a limiting factor that needs to be considered when embedding the electronic component in the substrate. Additionally, such a face-down embedded structure may allow optimization of the design routing. For example, current embedding structures such as those shown in FIG. 1 and FIG. 2 require a cavity formed in the core. As such, design features may not be included in the cavity area of the substrate. In accordance with certain aspects of the disclosure, certain embedded features are placed on the core layer so as not to sacrifice the cavity area of the core.

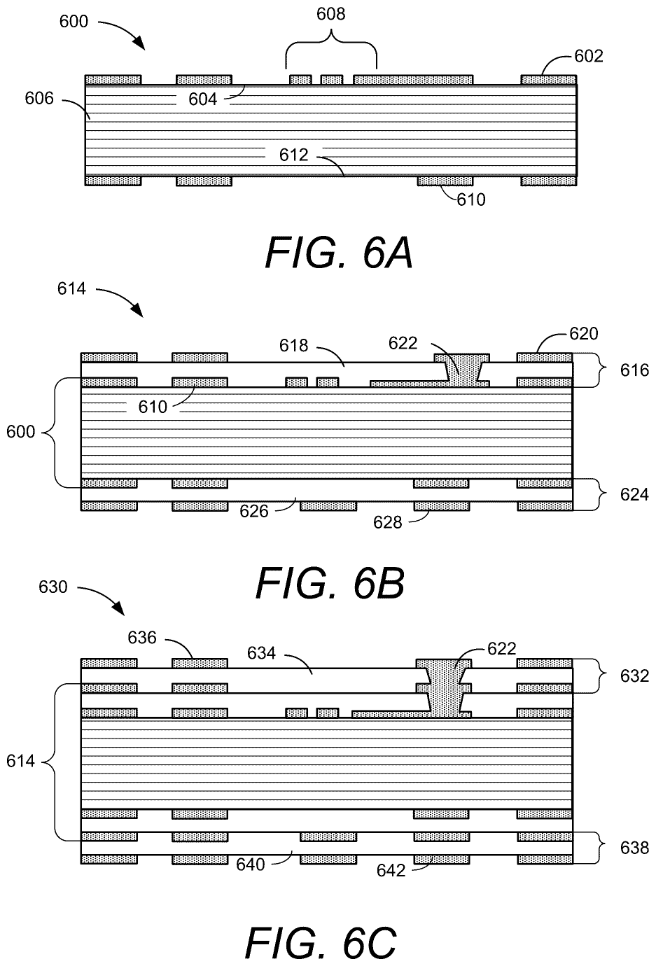

FIG. 4 is a cross-sectional view of an example substrate 400, according to aspects of the disclosure. In this example, the substrate 400 includes an electronic component 402 including a lower planar surface 404 having a first set of one or more metal terminals 406 providing an electrical connection with the electronic component 402. The substrate 400 further includes a core 408 having an upper planar surface 410 facing the lower planar surface 404 of the electronic component 402. The core 408 may include a patterned metallization layer 412 on the upper planar surface 410. In the example shown in FIG. 4, the patterned metallization layer 412 is connected to the first set of one or more metal terminals 406 of the electronic component 402 and a connection interface 414. In an aspect, the connection interface 414 includes solder connections that connect the first set of one or more terminals 406 to the patterned metallization layer 412. Additionally, or in the alternative, the connection interface 414 may be formed as thermocompression bonds that provide a metallurgical bond between the first set of one or more metal terminals 406 and the patterned metallization layer 412.

In the example shown in FIG. 4, one or more dielectric layers 416 are disposed over the upper planar surface 410 of the core 408. Although the dielectric layers 416 are shown in FIG. 4 as separate layers, it will be understood that multiple dielectric layers may be fused during the manufacturing process so as to appear and function as a single dielectric structure. Further, it will be understood that different layers of the dielectric layers 416 may be formed from different dielectric materials during the manufacturing process. In an aspect, different dielectric materials for the different dielectric layers may be used when one or more of the dielectric layers 416 are to have a different dielectric constant than another of the dielectric layers 416.

In accordance with certain aspects of the disclosure, the dielectric layers 416 include a cavity 418 in which the electronic component 402 is mounted. In accordance with certain aspects of the disclosure, the cavity 418 may be filled with a filler material 420, such as a dielectric material, to secure the electronic component 402 within the cavity 418. In an aspect, the filler material may completely fill the cavity 418 so that the entirety of the electronic component 402 is enclosed by the filler material 420. In an aspect, the filler material 420 may be comprised of the same dielectric material used to form the dielectric layers 416. Again, it will be understood that the filler material in the cavity 418 may be fused with the dielectric layers 416 so as to appear and function as a single dielectric structure that surrounds the electronic component 402. Further, it will be understood that the filler material 420 may comprise a material other than the dielectric material used to form the dielectric layers 416.

In accordance with certain aspects of the disclosure, one or more electrically conductive paths extend through the dielectric layers 416 between the patterned metallization layer 412 at the upper planar surface 410 of the core 408 and one or more metal terminals 422 at an upper planar surface 424 of the substrate 400. In FIG. 4, metal vias 426 and pads 427 provides such an electrically conductive path. In accordance with certain aspects of the disclosure, the metal terminals 422 may be configured for connection to an electronic circuit package (not shown in FIG. 4) mounted at the upper planar surface 424 of the substrate 400.

In an aspect, substrate 400 may include a further set of one or more dielectric layers 428 disposed on a lower surface 430 of the core 408. As shown, the dielectric layers 428 may separate the patterned metallization layers 432 from one another. One or more metal via structures may extend between the patterned metallization layers 432 and connect with one or more metal terminals 438. In accordance with various aspects of the disclosure, the one or more metal terminals 438 may be configured for mounting the substrate 400 to another substrate and/or to an electrical device package (not shown in FIG. 4).

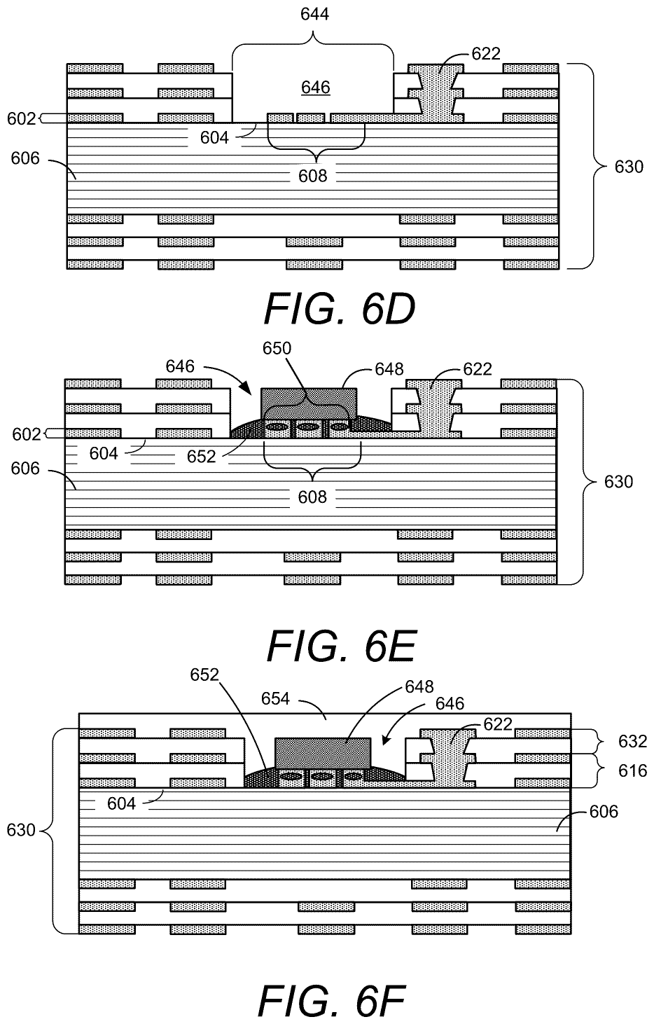

FIG. 5 is a cross-section of view of an example substrate 500, according to aspects of the disclosure. In this example, the substrate 500 is similar in most respects to substrate 400 shown in FIG. 5. Accordingly, like reference numbers have been used to reference similar elements. Unlike the substrate 400, the substrate 500 includes a non-conductive paste 502 disposed between the lower planar surface 404 of the electronic component 402 and the upper planar surface 410 of the core 408 to facilitate securement of the electronic component 402 in the cavity 418. In an aspect, the non-conductive paste 502 at least partially surrounds one or more sidewalls of the electronic component 402. In addition to facilitating mounting of the electronic component 402 in place in a completed substrate 500, the non-conductive paste 502 may also serve to hold the electronic component 402 in position during fabrication (e.g., filling of the cavity 418).

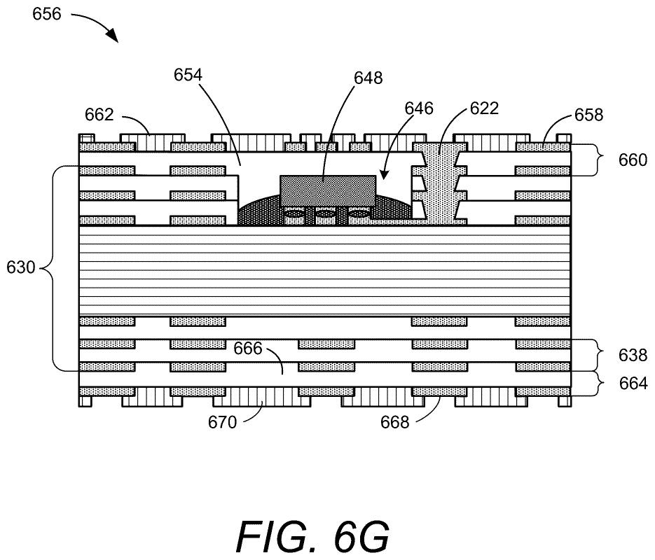

FIGS. 6A through 6G illustrate example steps undertaken in fabricating a substrate, according to aspects of the disclosure. As shown in FIG. 6A, a first intermediate structure 600 is formed with a patterned metallization layer 602 that is disposed over an upper surface 604 of a core 606. As described in further detail herein, conductive traces 608 of the patterned metallization layer 602 are configured for connection with the metal terminals of an electronic component. Additionally, a further patterned metallization layer 610 is formed over a lower surface 612 of the core 606.

As shown in FIG. 6B, the first intermediate structure 600 is subject to a layer build-up process to fabricate a second intermediate structure 614. During the layer build-up process, a layer 616 including a dielectric layer 618 and a patterned metallization layer 620 is formed over the upper surface of the first intermediate structure 600. In an aspect, formation of a metal via 622 that ultimately extends from the patterned metallization layer 610 to an upper surface of the substrate is started during the build-up of the layer 616. Additionally, a layer 624 including dielectric layer 626 and a patterned metallization layer 628 is formed over the lower surface of the first intermediate structure 600 during a layer build-up process.

As shown in FIG. 6C, the second intermediate structure 614 is subject to further layer build-up processing to fabricate a third intermediate structure 630. During the layer build-up process, a layer 632 including a dielectric layer 634 and patterned metallization layer 636 is formed over the upper surface of the second intermediate structure 614. In an aspect, formation of the metal via 622 continues during the build-up of the layer 632. Additionally, a layer 638 including dielectric layer 640 and a patterned metallization layer 642 is formed over the lower surface of the second intermediate structure 614 during a layer build-up process.

In FIG. 6D, a region 644 of the dielectric layers is removed from the third intermediate structure 630 to form a cavity 646 in which an electronic component may be inserted. As shown, at least a portion of the region 644 overlies the conductive traces 608 of the patterned metallization layer 602 to which the terminals of the electronic component are to be connected. In an aspect, all of the dielectric material in region 644 is removed to expose the conductive traces 608 and a portion of the upper surface 604 of the core 606.

In FIG. 6E, an electronic component 648 is inserted into the cavity 646 and the metal terminals 650 of the electronic component 648 are connected to the corresponding conductive traces 608 of the patterned metallization layer 602. In accordance with certain aspects of the disclosure, the metal terminals 650 may be soldered to the conductive traces 608 and/or subject to a thermocompression bonding operation to provide a metallurgical bond between the metal terminals 650 and the conductive traces 608.

In accordance with certain aspects of the disclosure, a non-conductive paste 652 may be deposited in the cavity 646 prior to insertion of the electronic component 648. In such scenarios, the non-conductive paste 652 may be used as an adhesive to initially secure the electronic component 648 to the upper surface 604 of the core 606 while executing the processes for connecting the metal terminals 650 to the conductive traces 608. Additionally, or in the alternative, the non-conductive paste 652 may be injected into the cavity 646 after the electronic component 648 has been inserted and the connections between the metal terminals 650 and conductive traces 608 and been established.

In FIG. 6F, the cavity 646 is filled with a filler material 654 to secure the electronic component 648 within the cavity 646. In an aspect, the filler material 654 may be in the form of a viscous resin that fills the cavity 646 before the resin is cured. In an aspect, the viscous resin may be a dielectric resin. In an aspect, the filler material 654 may be formed from the same dielectric material as the dielectric material in one or both layers 616 and 632. In an aspect, the viscous resin may be extended to cover the portions of layer 632 that remain after the creation of the cavity 646 in FIG. 6E. In an aspect, the viscous resin is only used to fill the cavity 646 and does not extend to cover the exposed portions of layer 632.

FIG. 6G shows a completed substrate 656, according to aspects of the disclosure. Here, a patterned metallization layer 658 is formed over the filler material 654 to form layer 660. The metal via 622 is also extended through layer 660 for connection to the patterned metallization layer 658. A plurality of metal terminals 662 may be formed at the upper surface of the substrate 656 to provide an electrical connection with the patterned metallization layer 658. As noted herein, the metal terminals 662 may be configured for connection with an electronic package of a surface-mounted device.

As shown in FIG. 6G, an additional build-up layer 664 including a dielectric layer 666 and a patterned metallization layer 668 are formed over layer 638 and the lower portion of the substrate 656. The plurality of metal terminals 670 are formed at the lower surface of the substrate 656 and are in electrical contact with the patterned metallization layer 668. As noted herein, the metal terminals 670 may be configured for connection with another electronic package of a surface-mounted device, connection with another substrate, or the like.

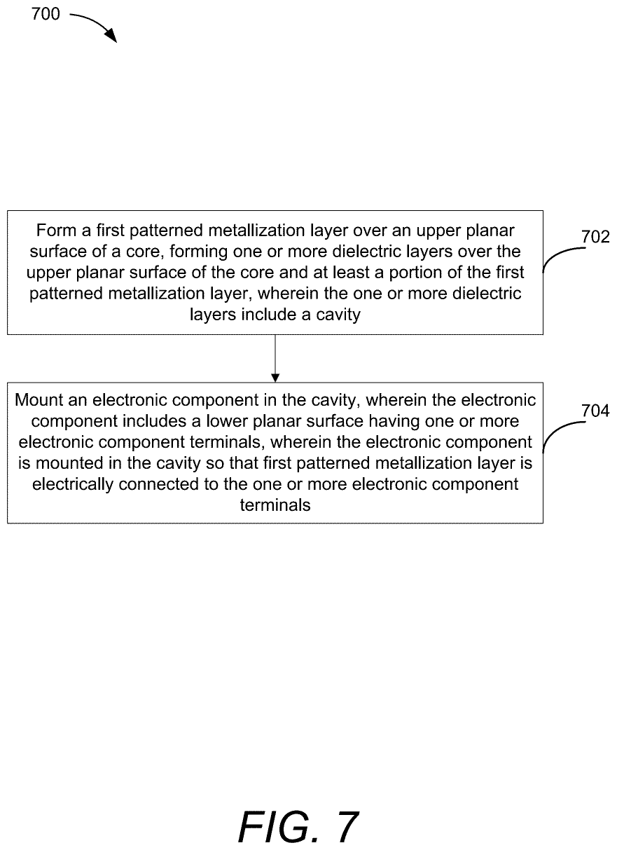

FIG. 7 is a flowchart showing an example method 700 for fabricating a substrate, according to aspects of the disclosure. At operation 702, a first patterned metallization layer formed over an upper planar surface of a core, forming one or more dielectric layers over the upper planar surface of the core and at least a portion of the first patterned metallization layer, wherein the one or more dielectric layers include a cavity. At operation 704, an electronic component is mounted in the cavity, wherein the electronic component includes a lower planar surface having one or more electronic component terminals, wherein the electronic component is mounted in the cavity so that first patterned metallization layer is electrically connected to the one or more electronic component terminals.

A technical advantage of the method 700 is that it may be used to form a substrate with an embedded electronic component (e.g., deep trench capacitor) and a core, where the fabrication processes are not dependent on the thickness of the core. Other technical advantages of the method 700 include 1) there are no limitations placed on the core thickness and electronic thickness, 2) there is no need to form a cavity in the core layer, 3) there is more design flexibility without the cavity in the core, and 4) short distance connections may be implemented thereby providing the substrate with electrical performance benefits.

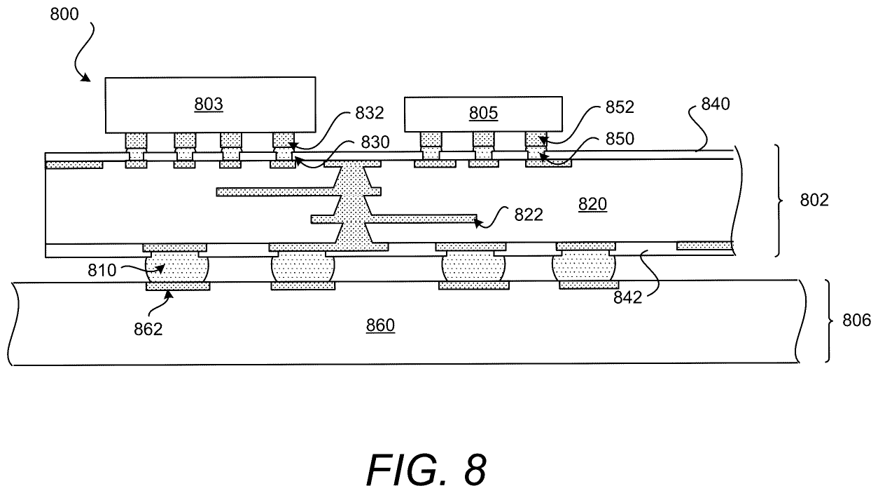

FIG. 8 illustrates a profile view of a package 800 that includes a surface mount substrate 802, an integrated device 803, and an integrated passive device 805 (e.g., a substrate having an embedded electronic component and a core), according to aspects of the disclosure. The package 800 may be coupled to a printed circuit board (PCB) 806 through a plurality of solder interconnects 810. The PCB 806 may include at least one board dielectric layer 860 and a plurality of board interconnects 862.

The surface mount substrate 802 includes at least one dielectric layer 820 (e.g., substrate dielectric layer), a plurality of interconnects 822 (e.g., substrate interconnects), a solder resist layer 840 and a solder resist layer 842. The integrated device 803 may be coupled to the surface mount substrate 802 through a plurality of solder interconnects 830. The integrated device 803 may be coupled to the surface mount substrate 802 through a plurality of pillar interconnects 832 and the plurality of solder interconnects 830. The integrated passive device 805 may be coupled to the surface mount substrate 802 through a plurality of solder interconnects 850. The integrated passive device 805 may be coupled to the surface mount substrate 802 through a plurality of pillar interconnects 852 and the plurality of solder interconnects 850.

The package (e.g., 800) may be implemented in a radio frequency (RF) package. The RF package may be a radio frequency front end (RFFE) package. A package (e.g., 800) may be configured to provide Wireless Fidelity (WiFi) communication and/or cellular communication (e.g., 2G, 3G, 4G, 5G). The package (e.g., 800) may be configured to support Global System for Mobile (GSM) Communications, Universal Mobile Telecommunications System (UMTS), and/or Long-Term Evolution (LTE). The package (e.g., 800) may be configured to transmit and receive signals having different frequencies and/or communication protocols.

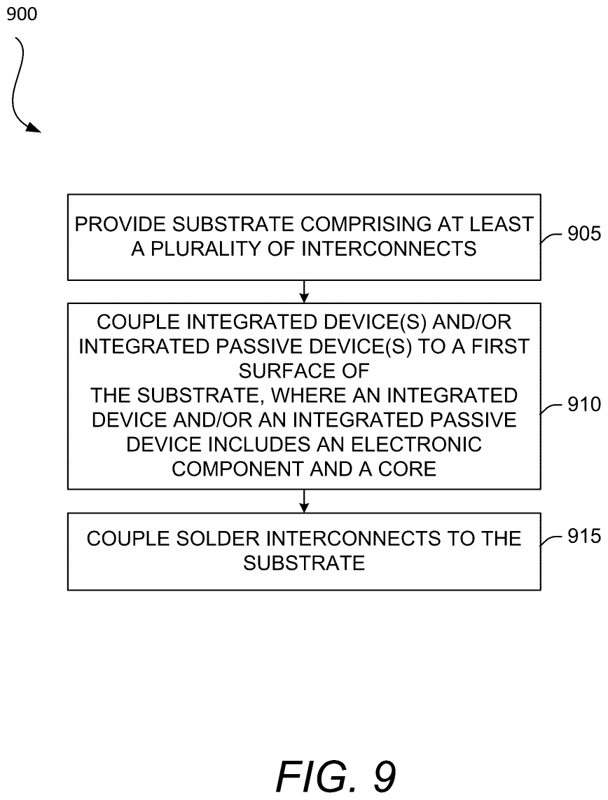

FIG. 9 illustrates an example method 900 for providing or fabricating a package that includes an integrated device comprising a substrate having an electronic component on a core, according to aspects of the disclosure. In some implementations, the method 900 of FIG. 9 may be used to provide or fabricate the package 800 of FIG. 8 described in the disclosure. However, the method 900 may be used to provide or fabricate any of the packages described in the disclosure.

It should be noted that the method of FIG. 9 may combine one or more processes in order to simplify and/or clarify the method for providing or fabricating a package that includes an integrated device comprising a magnetic layer and/or an integrated passive device comprising a magnetic layer. In some implementations, the order of the processes may be changed or modified.

The method provides (at 905) a surface mount substrate (e.g., 802). The surface mount substrate 802 may be provided by a supplier or fabricated. The surface mount substrate 802 includes at least one dielectric layer 820 and a plurality of interconnects 822. The surface mount substrate 802 may include an embedded trace substrate (ETS). In some implementations, the at least one dielectric layer 820 may include prepreg layers.

The method couples (at 910) at least one integrated device (e.g., 803) to the first surface of the substrate (e.g., 802). For example, the integrated device 803 may be coupled to the surface mount substrate 802 through the plurality of pillar interconnects 832 and the plurality of solder interconnects 830. The plurality of pillar interconnects 832 may be optional. The plurality of solder interconnects 830 are coupled to the plurality of interconnects 822. A solder reflow process may be used to couple the integrated device 803 to the plurality of interconnects through the plurality of solder interconnects 830.

The method also couples (at 910) at least one integrated passive device (e.g., 805) to the first surface of the substrate (e.g., 802). For example, the integrated passive device 805 may be coupled to the surface mount substrate 802 through the plurality of pillar interconnects 852 and the plurality of solder interconnects 850. The plurality of pillar interconnects 852 may be optional. The plurality of solder interconnects 850 are coupled to the plurality of interconnects 822. A solder reflow process may be used to couple the integrated passive device 805 to the plurality of interconnects through the plurality of solder interconnects 850.

The method couples (at 915) a plurality of solder interconnects (e.g., 810) to the second surface of the substrate (e.g., 802). A solder reflow process may be used to couple the plurality of solder interconnects 810 to the substrate.

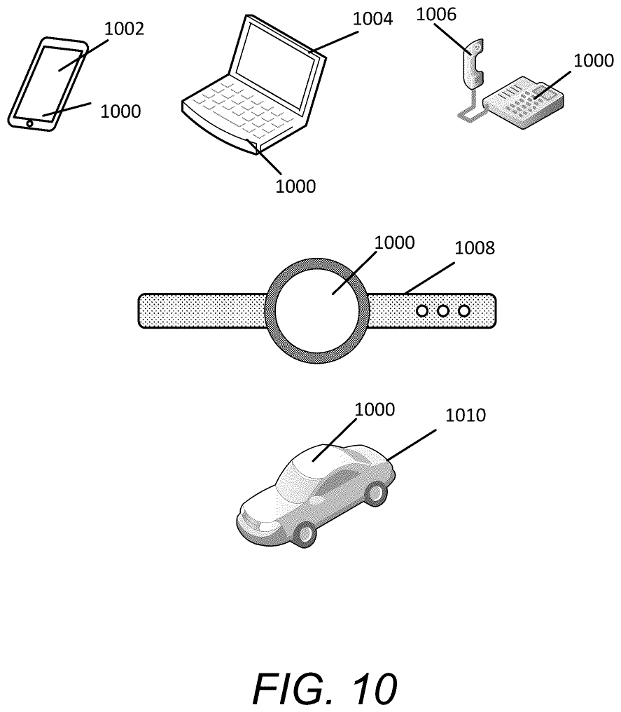

FIG. 10 illustrates various electronic devices that may be integrated with any of the aforementioned devices, integrated devices, integrated circuit (IC) packages, integrated circuit (IC) devices, semiconductor devices, integrated circuits, dies, interposer packages, package-on-package (PoP), System in Package (SiP), or System on Chip (SoC). For example, a mobile phone device 1002, a laptop computer device 1004, a fixed location terminal device 1006, a wearable device 1008, or automotive vehicle 1010 may include a device 1000 as described herein. The device 1000 may be, for example, any of the devices and/or integrated circuit (IC) packages described herein. The devices 1002, 1004, 1006 and 1008 and the vehicle 1010 illustrated in FIG. 10 are merely exemplary. Other electronic devices may also feature the device 1000 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

Implementation examples are described in the following numbered aspects:

Aspect 1. A substrate, comprising: an electronic component including a lower planar surface having one or more electronic component terminals, a core having an upper planar surface facing the lower planar surface of the electronic component; a patterned metallization layer over the upper planar surface of the core, wherein the patterned metallization layer is connected to the one or more electronic component terminals at the lower planar surface of the electronic component; one or more dielectric layers disposed over the upper planar surface of the core; and a cavity formed within the one or more dielectric layers, wherein the electronic component is located in the cavity and over the upper planar surface of the core.

Aspect 2. The substrate of aspect 1, wherein the substrate further comprises: one or more vias electrically connected to the patterned metallization layer and extending through the one or more dielectric layers; one or more metal terminals connected to the one or more vias, wherein the one or more metal terminals are configured to provide one or more electrical connections to an electronic package mounted to the substrate.

Aspect 3. The substrate of any of aspects 1 to 2, further comprising: a filler disposed in regions between sidewalls of the core and sidewalls of the electronic component.

Aspect 4. The substrate of aspect 3, wherein: the filler comprises a dielectric material.

Aspect 5. The substrate of aspect 4, wherein: the dielectric material of the filler comprises a same dielectric material as the one or more dielectric layers.

Aspect 6. The substrate of any of aspects 1 to 5, wherein: the patterned metallization layer is disposed on the upper planar surface of the core.

Aspect 7. The substrate of any of aspects 1 to 6, further comprising: a non-conductive paste disposed in the cavity between the lower planar surface of the electronic component and the upper planar surface of the core.

Aspect 8. The substrate of aspect 7, wherein: the non-conductive paste at least partially surrounds one or more sidewalls of the electronic component.

Aspect 9. The substrate of any of aspects 1 to 8, wherein: the one or more electronic component terminals are electrically connected to the patterned metallization layer by one or more electrical paths comprising one or more solder connections.

Aspect 10. The substrate of any of aspects 1 to 9, wherein: the one or more electronic component terminals are electrically connected to the patterned metallization layer by one or more electrical paths having one or more thermocompression bonds providing a metallurgical bond between the one or more electronic component terminals and the patterned metallization layer.

Aspect 11. The substrate of any of aspects 1 to 10, wherein: the core has a thickness that is greater than about 760 micrometers.

Aspect 12. The substrate of any of aspects 1 to 10, wherein: the core has a thickness that is greater than about 820 micrometers.

Aspect 13. The substrate of any of aspects 1 to 10, wherein: the core has a thickness that is greater than about 1240 micrometers.

Aspect 14. The substrate of any of aspects 1 to 13, wherein: the core has a thickness greater than a height of the electronic component.

Aspect 15. The substrate of any of aspects 1 to 14, wherein: the one or more dielectric layers include a plurality of dielectric layers having further patterned metallization layers respectively disposed over each dielectric layer of the plurality of dielectric layers.

Aspect 16. The substrate of any of aspects 1 to 15, wherein: the electronic component comprises a deep trench capacitor.

Aspect 17. An electronic device, comprising: a substrate including, an electronic component including a lower planar surface having one or more electronic component terminals, a core having an upper planar surface facing the lower planar surface of the electronic component; a patterned metallization layer over the upper planar surface of the core, wherein the patterned metallization layer is connected to the one or more electronic component terminals at the lower planar surface of the electronic component; one or more dielectric layers disposed over the upper planar surface of the core; and a cavity formed within the one or more dielectric layers, wherein the electronic component is located in the cavity and over the upper planar surface of the core.

Aspect 18. The electronic device of aspect 17, wherein: the electronic component comprises a deep trench capacitor.

Aspect 19. The electronic device of any of aspects 17 to 18, further comprising: an electronic circuit package mounted on the substrate and electrically connected to the one or more electronic component terminals.

Aspect 20. The electronic device of any of aspects 17 to 19, wherein the electronic device comprises at least one of: a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

Aspect 21. A method of forming a substrate, comprising: forming a first patterned metallization layer over an upper planar surface of a core, forming one or more dielectric layers over the upper planar surface of the core and at least a portion of the first patterned metallization layer; forming a cavity in the one or more dielectric layers; mounting an electronic component in the cavity, wherein the electronic component includes a lower planar surface having one or more electronic component terminals; and connecting the one or more electronic component terminals to the first patterned metallization layer.

Aspect 22. The method of aspect 21, further comprising: forming one or more metal vias electrically connected to the first patterned metallization layer and extending through the one or more dielectric layers; and terminating the one or more metal vias at one or more metal terminals, wherein the one or more metal terminals are configured to provide one or more electrical connections to an electronic package mounted to the substrate.

Aspect 23. The method of any of aspects 21 to 22, further comprising: forming a filler in regions between sidewalls of the core and sidewalls of the electronic component.

Aspect 24. The method of aspect 23, wherein: the filler comprises a dielectric material.

Aspect 25. The method of aspect 24, wherein: the dielectric material of the filler comprises a same dielectric material as the one or more dielectric layers.

Aspect 26. The method of any of aspects 21 to 25, wherein: the first patterned metallization layer is formed on the upper planar surface of the core.

Aspect 27. The method of any of aspects 21 to 26, further comprising: forming a non-conductive paste disposed between the lower planar surface of the electronic component and the upper planar surface of the core to facilitate mounting of the electronic component in the cavity.

Aspect 28. The method of aspect 27, wherein: the non-conductive paste at least partially surrounds one or more sidewalls of the electronic component.

Aspect 29. The method of any of aspects 21 to 28, wherein: the core has a thickness greater than a height of the electronic component.

Aspect 30. The method of any of aspects 21 to 29, wherein: the electronic component comprises a deep trench capacitor.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

It is noted that the figures in the disclosure may represent actual representations and/or conceptual representations of various parts, components, objects, devices, packages, integrated devices, integrated circuits, and/or transistors. In some instances, the figures may not be to scale. In some instances, for the purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metallization layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the detailed description above, it can be seen that different features are grouped together in examples. This manner of disclosure should not be understood as an intention that the example aspects have more features than are explicitly mentioned in each aspect. Rather, the various aspects of the disclosure may include fewer than all features of an individual example aspect disclosed. Therefore, the following aspects should hereby be deemed to be incorporated in the description, wherein each aspect by itself can stand as a separate example. Although each dependent aspect can refer in the aspects to a specific combination with one of the other aspects, the aspect(s) of that dependent aspect are not limited to the specific combination. It will be appreciated that other example aspects can also include a combination of the dependent aspect (s) with the subject matter of any other dependent aspect or independent aspect or a combination of any feature with other dependent and independent aspects. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of an aspect can be included in any other independent aspect, even if the aspect is not directly dependent on the independent aspect.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. A substrate, comprising:
an electronic component including a lower planar surface having one or more electronic component terminals,
a core having an upper planar surface facing the lower planar surface of the electronic component;
a patterned metallization layer over the upper planar surface of the core, wherein the patterned metallization layer is connected to the one or more electronic component terminals at the lower planar surface of the electronic component;
one or more dielectric layers disposed over the upper planar surface of the core; and
a cavity formed within the one or more dielectric layers, wherein the electronic component is located in the cavity and over the upper planar surface of the core.

2. The substrate of claim 1, wherein the substrate further comprises:
one or more vias electrically connected to the patterned metallization layer and extending through the one or more dielectric layers;
one or more metal terminals connected to the one or more vias, wherein the one or more metal terminals are configured to provide one or more electrical connections to an electronic package mounted to the substrate.

3. The substrate of claim 1, further comprising:
a filler disposed in regions between sidewalls of the core and sidewalls of the electronic component.

4. The substrate of claim 3, wherein:
the filler comprises a dielectric material.

5. The substrate of claim 4, wherein:
the dielectric material of the filler comprises a same dielectric material as the one or more dielectric layers.

6. The substrate of claim 1, wherein:
the patterned metallization layer is disposed on the upper planar surface of the core.

7. The substrate of claim 1, further comprising:
a non-conductive paste disposed in the cavity between the lower planar surface of the electronic component and the upper planar surface of the core.

8. The substrate of claim 7, wherein:
the non-conductive paste at least partially surrounds one or more sidewalls of the electronic component.

9. The substrate of claim 1, wherein:
the one or more electronic component terminals are electrically connected to the patterned metallization layer by one or more electrical paths comprising one or more solder connections.

10. The substrate of claim 1, wherein:
the one or more electronic component terminals are electrically connected to the patterned metallization layer by one or more electrical paths having one or more thermocompression bonds providing a metallurgical bond between the one or more electronic component terminals and the patterned metallization layer.

11. The substrate of claim 1, wherein:
the core has a thickness that is greater than about 760 micrometers.

12. The substrate of claim 1, wherein:
the core has a thickness that is greater than about 820 micrometers.

13. The substrate of claim 1, wherein:
the core has a thickness that is greater than about 1240 micrometers.

14. The substrate of claim 1, wherein:
the core has a thickness greater than a height of the electronic component.

15. The substrate of claim 1, wherein:
the one or more dielectric layers include a plurality of dielectric layers having further patterned metallization layers respectively disposed over each dielectric layer of the plurality of dielectric layers.

16. The substrate of claim 1, wherein:
the electronic component comprises a deep trench capacitor.

17. An electronic device, comprising:
a substrate including,
an electronic component including a lower planar surface having one or more electronic component terminals,
a core having an upper planar surface facing the lower planar surface of the electronic component;
a patterned metallization layer over the upper planar surface of the core, wherein the patterned metallization layer is connected to the one or more electronic component terminals at the lower planar surface of the electronic component;
one or more dielectric layers disposed over the upper planar surface of the core; and
a cavity formed within the one or more dielectric layers, wherein the electronic component is located in the cavity and over the upper planar surface of the core.

18. The electronic device of claim 17, wherein:
the electronic component comprises a deep trench capacitor.

19. The electronic device of claim 17, further comprising:
an electronic circuit package mounted on the substrate and electrically connected to the one or more electronic component terminals.

20. The electronic device of claim 17, wherein the electronic device comprises at least one of:
a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

21. A method of forming a substrate, comprising:
forming a first patterned metallization layer over an upper planar surface of a core,
forming one or more dielectric layers over the upper planar surface of the core and at least a portion of the first patterned metallization layer;
forming a cavity in the one or more dielectric layers;
mounting an electronic component in the cavity, wherein the electronic component includes a lower planar surface having one or more electronic component terminals; and
connecting the one or more electronic component terminals to the first patterned metallization layer.

22. The method of claim 21, further comprising:
forming one or more metal vias electrically connected to the first patterned metallization layer and extending through the one or more dielectric layers; and
terminating the one or more metal vias at one or more metal terminals, wherein the one or more metal terminals are configured to provide one or more electrical connections to an electronic package mounted to the substrate.

23. The method of claim 21, further comprising:
forming a filler in regions between sidewalls of the core and sidewalls of the electronic component.

24. The method of claim 23, wherein:
the filler comprises a dielectric material.

25. The method of claim 24, wherein:
the dielectric material of the filler comprises a same dielectric material as the one or more dielectric layers.

26. The method of claim 21, wherein:
the first patterned metallization layer is formed on the upper planar surface of the core.

27. The method of claim 21, further comprising:
forming a non-conductive paste disposed between the lower planar surface of the electronic component and the upper planar surface of the core to facilitate mounting of the electronic component in the cavity.

28. The method of claim 27, wherein:
the non-conductive paste at least partially surrounds one or more sidewalls of the electronic component.

29. The method of claim 21, wherein:
the core has a thickness greater than a height of the electronic component.

30. The method of claim 21, wherein:
the electronic component comprises a deep trench capacitor.
